(19) United States
(12) Patent Application Publication
(10) Pub. No.: US 2025/0210930 A1
(43) Pub. Date: Jun. 26, 2025

(54) PHOTONIC SYSTEM COMPRISING A LASER SOURCE CAPABLE OF EMITTING MULTISPECTRAL LIGHT RADIATION

(71) Applicant: SCINTIL PHOTONICS, GRENOBLE (FR)

(72) Inventors: Sylvie Menezo, Grenoble (FR); Florian Enault, Begard (FR)

(73) Assignee: SCINTIL PHOTONICS, GRENOBLE (FR)

(21) Appl. No.: 18/842,633

(22) PCT Filed: Jan. 13, 2023
(86) PCT No.: PCT/EP2023/050708

§ 371 Date: Aug. 29, 2024

(30) Foreign Application Priority Data
Mar. 15, 2022 (FR) FR2202254

(51) Int. Cl. H01S 3/107; H01S 3/23

(52) U.S. Cl. CPC H01S 3/107; H01S 3/23

(57) ABSTRACT

The invention relates to a photonic system comprising a laser source capable of emitting at least one multispectral light radiation. The photonic system comprises a photonic component having a plurality of tunable optical filters respectively having a plurality of resonant frequencies. The photonic system also comprises a photodetector arranged downstream of the component to establish a signal representative of the multispectral radiation, a modulator associated with the bank of tunable lasers. The laser source also comprises a locking device configured to process the signal representative of the multispectral radiation and to adjust the resonant frequency of a tunable optical filter of the photonic component to the emission frequency of the light radiation of a laser of the bank.

### FIELD OF THE INVENTION

The present invention relates to a laser source for emitting light radiation having a plurality of spectral lines separated by a given spectral interval. Such a source is particularly useful in the field of wavelength-division multiplexing communications.

### BACKGROUND OF THE INVENTION

The document “WDM Source Based on High-Power, Efficient 1280-nm DFB Lasers for Terabit Interconnect Technologies,” B. Buckley, IEEE PHOTONICS TECHNOLOGY LETTERS, VOL. 30, NO. 22, Nov. 15, 2018, proposes a laser source formed from a bank of distributed feedback lasers. Each laser comprises a Bragg grating distributed along the laser cavity. The lasers emit light emissions at stepped wavelengths, typically separated from one another by 100 GHz or 50 GHz.

The light emissions emitted by the lasers are propagated to the input ports of a passive optical mixer. This mixer produces, on its output ports, a plurality of light emissions each combining the light emissions provided on the input ports. The output emissions produced on these output ports are therefore multi-spectral (in a spectral comb, each line of the comb corresponding to the emission emitted by a laser of the bank).

Due to inaccuracies and variability in laser manufacturing processes, laser emission wavelengths are poorly controlled. This leads to variability in the spectral interval between two spectral lines in multispectral radiation, ranging from plus or minus 5% to 10% of the expected spectral interval, or even more depending on the interval. The wavelengths of light radiation emitted by lasers are also sensitive to operating temperature, which can vary from 0 to 80° C.

The spectral range of the light radiation provided by a multispectral laser source of the state of the art is therefore poorly controlled and liable to drift during operation of the source.

The paper “Streamlined Architecture for Thermal Control and Stabilization of Cascaded DWDM Micro-Ring Filters Bus” presented by Maarten Hattink at the Optical Fiber Conference, held Mar. 6-10, 2022, proposes a solution to compensate for this limitation. The approach adopted in this paper aims to lock filters onto the emission frequencies of multispectral laser sources. To this end, the resonant frequencies of the filters are modulated to produce feedback signals from the resonant frequencies of the filters. However, this approach requires calibration of the device, which makes the solution particularly cumbersome to operate. The choice of modulation frequencies proposed in this document leads to the introduction of error terms on the feedback signals. This configuration runs the risk of locking several modulators to a single transmission frequency.

### OBJECT OF THE INVENTION

One aim of the invention is to provide at least a partial solution to this problem. More specifically, one aim of the invention is to propose a laser source capable of providing multispectral light radiation whose spectral range is better controlled than that present in the light radiation produced by laser sources of the state of the art. Another aim of the invention is to provide a laser source for locking a tunable resonant frequency of at least one filter of a photonic component.

### BRIEF DESCRIPTION OF THE INVENTION

In order to achieve this aim, the object of the invention proposes a photonic system

comprising a laser source capable of emitting at least one multispectral light beam having a plurality of spectral lines, the photonic system comprising:
A laser bank comprising a plurality of lasers, a spectral line of multispectral light radiation corresponding to an emission frequency of a laser in the bank;
a modulator associated with the bank of lasers, the modulator being configured to generate a modulation signal and to modulate the emission frequency of at least one laser in the bank;
a photonic component arranged downstream of the laser bank and comprising a plurality of tunable optical filters each having a plurality of resonant frequencies;
A photodetector arranged downstream of the photonic component to establish a signal representative of multispectral radiation produced by the photonic component;
a locking device configured to process the signal representative of the multispectral radiation and to adjust the resonant frequencies of the tunable optical filters of the photonic component to the emission frequencies of the bank's lasers.

According to other advantageous non-limiting features of the invention, taken alone or according to any technically feasible combination:
the tunable optical filters of the photonic component are ring micro-resonators;
the tunable optical filters are each equipped with devices for adjusting their resonant frequency;
the resonant frequency adjustment devices are heaters;
the lasers are distributed feedback lasers or distributed Bragg reflector lasers;
the locking device is configured to control the modulator and select, by means of a selection signal, a laser from the bank to which the modulation signal is applied;
the modulator generates a plurality of mutually distinct modulation signals, the modulation signals being applied to the lasers in the bank; the resonant frequencies of the tunable optical filters are adjusted one optical filter at a time;
the modulator is configured to produce a sinusoidal modulation signal having a modulation frequency;
the locking device is configured to establish a measurement representative of the power present in a second harmonic of the modulation frequency of the signal representative of the multispectral radiation;
the locking device is configured to establish a measurement representative of the power present in a principal component of the modulation frequency of the signal representative of the multispectral radiation;
the locking device is configured to establish a measurement representative of the phase of the main component of the modulation frequency of the signal representative of the multispectral radiation;
the photonic component is a radio-frequency modulator;
the photonic component is a radio-frequency demodulator.

### BRIEF DESCRIPTION OF THE FIGURES

Other features and advantages of the invention will emerge from the following detailed description of the invention with reference to the appended figures, in which:

FIGS. 1a, 1b, 1c, 1d and 1e show schematic diagrams of the principles underlying the invention;

FIG. 2a shows a first aspect of the invention;

FIGS. 2b and 2c show two variants of the first aspect of the invention;

FIG. 3a shows the transition from a natural state to a locked state;

FIG. 3b shows an advantageous feature of a filter transmission function of a laser source according to a first aspect of the invention;

FIG. 3c shows the calibration of a filter of a laser source according to a first aspect of the invention;

FIGS. 4 and 5 show further embodiments of a first aspect of the invention;

FIG. 6 shows the signal provided by the photodetector in the frequency domain, as shown in the embodiment of FIG. 5;

FIG. 7 shows a variant which can be applied to all embodiments of the first aspect of the invention;

FIGS. 8a, 8b and 8c show a second aspect of the invention;

FIG. 9a shows a modulator that can be used in a photonic system according to the second aspect of the invention;

FIG. 9b shows a calibration of a modulator according to the second aspect of the invention;

FIG. 9c shows a demodulator that can be used in a photonic system according to the second aspect of the invention; and

FIG. 9d shows the calibration of a demodulator according to the second aspect of the invention.

### DETAILED DESCRIPTION OF THE INVENTION

### Principle of the Invention

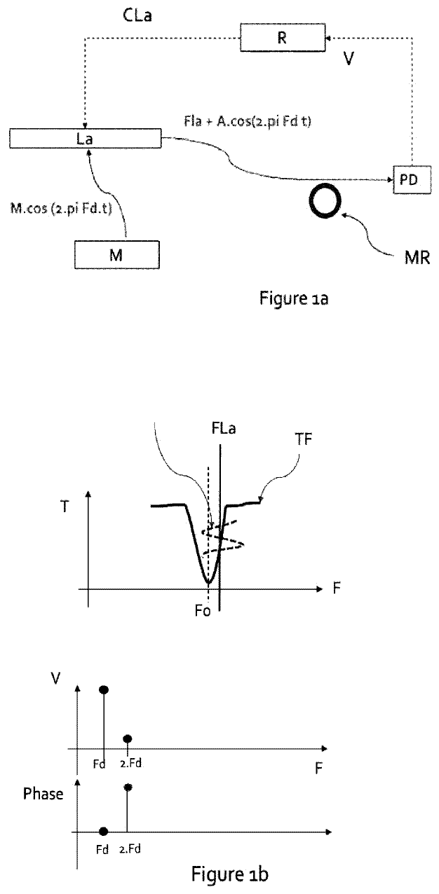

FIGS. 1a, 1b, 1c, 1d and 1e are schematic diagrams of the principles underlying the invention. In the architecture shown in FIG. 1a, light radiation from a tunable laser La is guided to a ring resonator MR, forming a filter with a resonant frequency FO, and to a photodetector PD downstream of the resonator MR.

The term “tunable laser” refers to a laser that produces light whose frequency (“emission frequency”) can be adjusted. By way of illustration, a means of adjusting the emission frequency with which the laser may be provided may comprise a device configured to modify its supply current, temperature, index and free-carrier concentration. A tunable laser can be provided with a plurality of means for adjusting its emission frequency, such as an adjustable current source and a heater for modifying the laser's operating temperature.

A modulator M, connected to a laser emission frequency adjustment means, is configured to modulate the emission frequency Fia of the light radiation emitted by the tunable laser La, by a modulation frequency Fd. This modulation frequency Fd, for example 5 kHz, is relatively low compared to the laser emission frequency, for example 200 terahertz. The amplitude of this modulation is also low. By way of example, 1 mA of supply current modulation amplitude can lead to a variation in the emission frequency FLa of the tunable laser La of the order of plus or minus 1 GHZ. The light emitted by the tunable laser La therefore varies at very low frequency Fd and with low amplitude A (1 GHZ) around its fundamental frequency FLa. The laser frequency therefore varies as Fia+A·cos(2pi·Fd·t).

FIG. 1b shows the frequency-domain transmission function T of the filter MR, whose spectrum TF has a resonant frequency F0, and the signal V supplied by this photodetector PD in the case where the emission frequency FLa of the tunable laser La is not locked to a resonant frequency F0 of the resonator MR, but has an emission frequency Fia higher than this resonant frequency F0. As the emission frequency of the tunable laser La is located in a relatively linear section of the transmission function of the resonator MR, the signal V supplied by the photodetector PD has, in the frequency domain, a main component Fd (corresponding to the modulation frequency) that is relatively large with respect to its harmonics, and in particular with respect to its second harmonic 2*Fd. In addition, the phase of the main component Fd of the signal V is reduced, that is, this main component is in phase with the signal V supplied by the photodetector PD.

Similar to FIG. 1b, FIG. 1c shows the transmission function T of the filter MR, whose spectrum TF has a resonant frequency F0, and the signal V supplied by this photodetector PD in the case where the emission frequency FLa′ of the tunable laser La is aligned with the resonant frequency FO of the resonator MR. In this case, the emission frequency FLa' of the tunable laser La is arranged in a relatively non-linear section of the transmission function of the resonator MR. As a result, the signal V supplied by the photodetector PD has relatively large 2*Fd harmonic components in the frequency domain, relative to the modulation frequency Fd.

Finally, FIG. 1d shows the frequency-domain transmission function T of the filter MR, whose spectrum TF has a resonant frequency F0. and the signal V supplied by this photodetector PD in the case where the emission frequency FLa of the tunable laser La is not aligned with a resonant frequency F0 of the resonator MR, but has an emission frequency Fla′ lower than this resonant frequency F0. As the emission frequency of the tunable laser La is located in a relatively linear section of the transmission function of the resonator MR, the signal V supplied by the photodetector PD has, in the frequency domain, a main component Fd that is relatively large with respect to its harmonics, and in particular with respect to its second harmonic 2*Fd. Furthermore, the phase of the main component Fd of the signal V is important, that is, this main component is in phase opposition with the signal V supplied by the photodetector.

FIG. 1e summarizes the results of FIGS. 1b, 1c and 1d and shows, in the upper graph, the evolution of the power present in the main component Fd and in the second harmonic 2*Fd of the signal V supplied by the photodetector when the emission frequency FLa of the tunable laser La is modified and the resonant frequency of the filter remains fixed (or vice versa). FIG. 1e also shows, in the lower graph, the evolution of the phase of the main component Fd of the signal V supplied by the photodetector.

Returning to the description of the schematic diagram in FIG. 1a, a locking device R receives the signal V established by the photodetector and processes it to produce a command CLa for the tunable laser La to tune its emission frequency to the resonant frequency F0 of the resonator MR. The processing implemented by the locking device R takes advantage of the results presented in FIGS. 1b, 1c, 1d, 1e and determines the control to be applied to the laser emission frequency adjustment means, which optimizes the proportion of the signal present in the main component or in the second harmonic 2*Fd of the signal supplied by the photodetector PD. Note that the proportion of the signal present in the main component and the proportion of the signal present in the second harmonic 2*Fd are related to one another, as can be clearly seen in FIG. 1e, so one and/or the other can be exploited as required. The phase can also be exploited as shown above.

By way of illustration, the locking device R can apply to the adjustment device a sequence of commands CLa incrementing from a minimum value to a maximum value so that the laser emission frequency La is adjusted, in a succession of steps, from a minimum emission frequency to a maximum emission frequency. At each step, the locking device R applies a frequency transformation to the signal supplied by the photodetector (e.g., a Fourier transform) in order to detect the proportion of the signal present in the second harmonic and/or in the main component. At the end of these steps, the step and the associated control Cla are identified which have led to a signal maximum in the second harmonic (or a signal minimum in the main component), this associated command CLa being the one that best matches the laser emission frequency La and the resonant frequency of the filter MR. This command is then applied to the device for adjusting the laser emission frequency La in order to cause the system to lock. Other approaches are also possible, for example by using the phase information of the main frequency Fd of the signal supplied by the photodetector PD in a control loop that increments or decrements by a predetermined step the Cia command supplied to the frequency adjustment device. As already noted, this information indicates whether the laser emission frequency is below the laser resonant frequency (high phase), or above it (zero or low phase).

The laser emission frequency La can be matched to the resonant frequency of the filter MR, as shown by way of example. Alternatively, they can be positioned at a specific distance from one another. Generally speaking, the control CLa is determined by optimizing a function that takes into account the proportion of the signal present in the main component and/or in the second harmonic 2*Fd of the control signal V. The optimization criterion may be that the function reaches a target value, is below a predetermined ceiling value, or is above a predetermined threshold value. It may also be provided for to use the phase of the main component and/or the second harmonic 2*Fd of the control signal V.

For example, the ratio between the proportion of the signal present in the second harmonic and the proportion of the signal present in the main component can be set to equal a target value, or to be maximized.

For the sake of precision, it will be said that the system is “locked” when the chosen optimization criterion is satisfied. This may correspond to the situation where the emission frequency Fia and the resonant frequency FO match, or where these frequencies are offset from one another by a specified distance.

Note that by applying a sinusoidal modulation signal, the appearance of harmonics in the signal supplied by the photodetector PD is limited (by comparison with square-wave modulation, for example), as the harmonics detected by the locking device R are then well representative of the quality of the locking between the transmission frequency and the resonant frequency.

Note also that the same locking principles are applicable to a configuration in which the adjustment device is associated with the filter so as to adjust its resonant frequency.

### First Aspect of the Invention

According to a first aspect, the present description exploits the principles just presented to propose a laser source of multispectral light radiation, thus presenting a plurality of spectral lines, these spectral lines being separated by a controlled spectral interval. By way of example, for applications in the field of wavelength-division multiplexing transmission, the aim is to provide a laser source of multispectral light radiation whose spectral lines are precisely separated (to within 5%) by an interval of, for example, 100 GHz or 50 GHz.

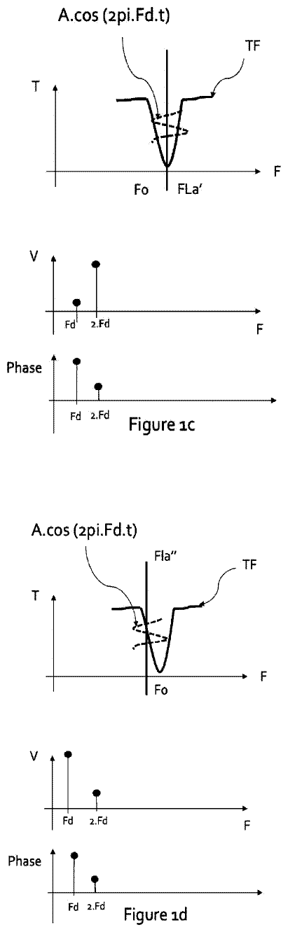

Referring to FIG. 2a, which shows a first embodiment of the invention, such a source 1 comprises a bank B of tunable lasers La, Lb, Lc. For example, the tunable lasers in bank B can be distributed feedback lasers. As is well known, each laser comprises a Bragg grating distributed along a laser cavity. Each laser La, Lb, Lc in bank B is associated with a current source Sa, Sb, Sc, enabling it to be powered and light radiation to be generated. As already noted, the emission frequency of a distributed feedback laser is dependent on its supply current. By adjusting this current, this emission frequency can be adjusted, making these lasers “tunable” in the sense of the present description. Bank B can contain any number of tunable lasers, typically between 4 and 100 lasers. Of course, the invention is by no means limited to a bank of distributed feedback lasers, and applies to any tunable laser. It may be a DBR (Distributed Bragg Reflector laser).

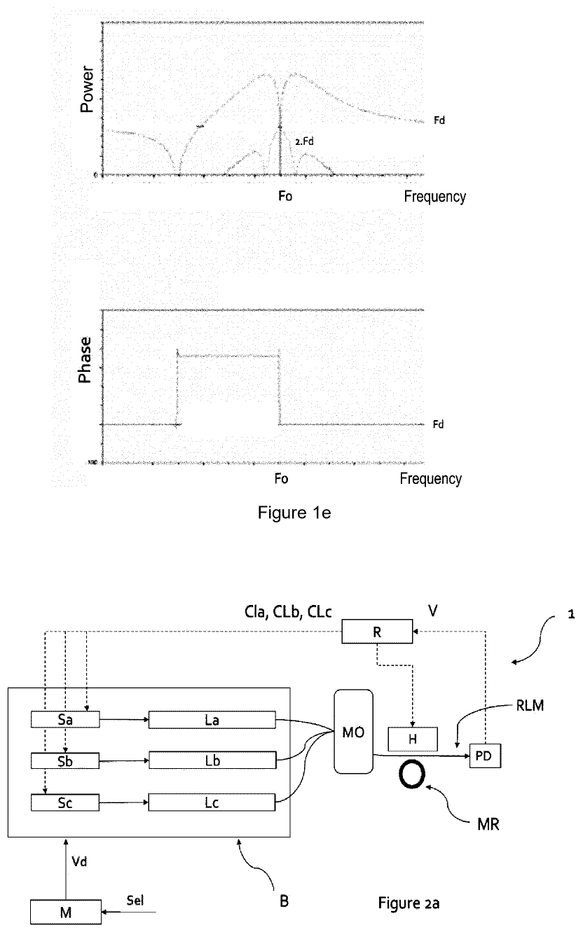

Bank B lasers are designed to emit light with staggered emission frequencies, typically within a 100 GHz spectral range for WDM applications, as previously described. However, as can be seen on the left-hand side of FIG. 3a (showing the frequencies Fla, Flb, Flc and the transfer function of filter FT), the variability of the Bank B manufacturing process means that the spectral interval separating the emission frequencies FLa, FLb, FLc of Bank B lasers cannot be perfectly controlled. The spectral interval separating two successive lasers (ordered by emission frequency) is therefore variable, and this variation in the absence of any locking mechanism can be of the order of +/−20% or more. It may also be noted that the operating temperature of bank B can affect and drift laser emission frequencies.

Returning to the embodiment description in FIG. 2a, the bank's tunable lasers La, Lb, Lc are coupled to an optical mixer MO via waveguides. This mixer MO produces at least one multispectral light beam RLM, one spectral line of which corresponds to an emission frequency of the light beam emitted by a tunable laser from bank B. The mixer MO can provide a plurality of mutually identical multispectral light radiations.

The multispectral light radiation RLM (or a plurality of such radiations) forms the so-called “useful” radiation of source 1, that is, the radiation that can be used by other elements, such as optical modulators, optical routers, etc., when source 1 forms a component of a communication system for example. According to one aspect of the invention, at least part of the “useful” multispectral radiation is sampled to enable the emission frequencies of the tunable lasers in bank B to be aligned with a frequency comb having a specific spectral interval.

This sampled part of the multispectral light radiation is guided to an optical filter MR with a transfer function TF defining a frequency comb template with the determined spectral interval DF, as shown in FIG. 3a. In other words, two successive resonant frequencies F0i, F0j, F0k of the filter MR are separated by a determined spectral interval DF. By way of example, the optical filter MR can be a resonator, such as a micro-ring resonator or a Fabry Perrot resonator, which enables the spectral interval DF between two resonant frequencies F0i, F0j, F0k to be precisely controlled, to within 5% for example. Whatever its nature, the optical filter MR is positioned downstream of the bank B of tunable lasers, and more precisely downstream of the optical mixer MO, to receive the multispectral light radiation RLM. In order to be able to discriminate with sufficient sensitivity a frequency deviation imparted by the modulation, the transfer function of the filter MR must be particularly narrow, preferentially presenting a slope greater than 6 dB/GHz when deviating by one gigahertz or more from one of its resonant frequencies. Such a feature is shown in FIG. 3b.

The optical filter MR can include a device for adjusting the plurality of its resonant frequencies F0i, F0j, F0K. Thus, when the filter MR is implemented by a ring resonator, this device can be a heater H for frequency shifting the natural frequency comb, as will be explained in detail in a later section of this description.

The source 1 shown in FIG. 2a also includes a photodetector PD arranged downstream of the optical filter MR to establish a signal V representative of the multispectral light radiation MLR.

It also includes a modulator M associated with the tunable laser bank B, the modulator M being controllable via a selection signal Sel. The function of the modulator M is to supply a signal Vd modulating the emission frequency of the light radiation emitted by a tunable laser with a frequency modulation signal Fd. The modulation signal Vd, whose general form is of the cos(2·Pi*Fd*t) type, has a relatively low modulation frequency Fd, of the order of a few kHz to a few MHz, typically of the order of 5 kHz, some 10 KHz, or even 1 MHz or more. The amplitude of the modulation signal Vd is chosen so that the frequency deviation of the emission frequency of the light radiation emitted by a tunable laser is of the order of 1 GHz or more. The selection signal Sel in this embodiment selects the tunable laser from bank B to which the modulation frequency Fd is to be applied.

In practice, this frequency modulation can be applied by modulating the current produced by the current source Sa, Sb, Sc associated with the selected tunable laser La, Lb, Lc with the modulation signal Vd. Other means of modulating the laser emission frequency can also be used. This may involve applying the modulation signal Vd to a heater associated with the laser, or to a free-carrier injection/depletion device in the laser. Generally speaking, then, the modulator M is electrically connected to the laser bank so as to apply the modulation signal to a means of adjusting the emission frequency with which the selected tunable laser is equipped.

Finally, laser source 1 shown in FIG. 2a includes a locking device R for a tunable laser from laser bank B. This locking device R is connected to the laser bank B via controls CLa, CLb, CLc respectively connected to current sources Sa, Sb, Sc. It is also connected to the photodetector PD to receive the signal V set by this element and, if present, to the heater H of the filter MR to control it. The locking device R is configured to control the modulator M and to select, by means of the selection signal Sel, the tunable laser to which the modulation signal Vd is applied. The locking device R is also configured, in this aspect of the invention, to implement a control loop aimed at tuning the selected tunable laser emission frequency Fla, Flb, Flc and locking it to a filter resonant frequency Foi, Foj, Fok. This control loop implements the principles described in relation to FIGS. 1a to 1e. In particular, it can perform a Fourier transform (or any other transformation in the frequency domain) of the signal V produced by the photodetector PD and determine the proportion of power present in the modulation frequency Fd and in its harmonics, particularly in the second harmonic. On this basis, the locking device R can generate the control associated with the selected tunable laser, enabling its emission frequency to be adjusted to lock onto a resonant frequency of the filter MR.

In the embodiment shown in FIG. 2a, current sources Sa, Sb, Sc are adjustable, and adjustment of a laser's emission frequency is achieved by feedback control of its average supply current supplied by the associated adjustable current source. As already stated, this average current, that is, the DC part of the laser supply current, affects the laser's emission frequency.

The laser source 1 of the embodiment shown in FIG. 2a is implemented by successively selecting a tunable laser to be locked from the tunable lasers of bank B. Thus, the locking device R may comprise a state machine emitting a selection signal Sel circularly selecting one of the tunable lasers from bank B, for example during successive locking periods whose duration may typically be between a few microseconds and a few milliseconds. During each locking period, the locking device R implements the processes required to lock the emission frequency of the selected tunable laser to the natural frequency FO closest to the optical filter MR. At the end of a complete cycle, each tunable laser is locked onto a specific frequency of the optical filter. In this locked state of bank B. shown on the right-hand side of FIG. 3a, the multispectral light radiation RLM conforms to the spectral template imposed by the optical filter MR: it presents a plurality of spectral lines FLa, FLb, FLc separated from one another by a spectral interval DF determined by the optical filter. As the spectral interval DF between two adjacent natural frequencies FO of the filter is controlled, typically to within 5% or better, this property can be imparted to the emission frequencies of the tunable lasers in bank B.

By repeating the control cycles one after the other in time-division multiplexing, the locked state of the bank of tunable lasers on the filter can be maintained over time, and any drifts compensated for, particularly those caused by variations in laser temperature.

Optionally, the locking device R can implement a further control loop to calibrate the resonant frequency comb of the optical filter MR and align it with absolute target resonant frequencies. To this end, and as shown in FIG. 2b, light radiation from a standard laser Le is supplied to a port complementary to the filter MR. This standard laser Le has a modulated emission frequency, just like the other tunable lasers La, Lb, Lc in bank B. However, standard tunable laser Le is not connected to locking device R, and its naturally stable emission frequency is not adjusted by this device.

The locking device R can extract from the Fourier transform of the signal V produced by the photodetector PD, the frequency components corresponding to the modulation frequency of the tunable standard laser and the locking device R can control the heater H, or any other device for adjusting the plurality of resonant frequencies F0i, F0j, F0k of the filter, in order to frequency shift this comb of natural frequencies and realign it with the target frequency supplied by the standard laser. This operation is shown in FIG. 3c. This calibration control loop of the filter MR and the tunable laser locking control loop are not necessarily distinct from one another, and according to one possible approach, the locking device R implements a single control loop or processes aimed at simultaneously optimizing the laser source 1 and the filter MR in order to produce a multispectral light beam RLM presenting a plurality of determined spectral lines, that is, each line of which is precisely positioned in the frequency domain.

FIG. 2c shows another variant of this first aspect of the invention. In this variant, the optical filter MR includes a device H for adjusting the plurality of its resonant frequencies F0i, F0j, F0k, for example a heater. The signal Vd supplied by the modulator M is, in this variant, applied to the adjustment device H of optical filter MR. The application of this signal therefore results in the simultaneous modulation, at modulation frequency Fd, of the plurality of resonant frequencies F0i, F0j, F0k of the optical filter MR. This variant offers the advantage of simpler implementation. The laser source 1 shown in FIG. 2c is implemented by successively selecting a tunable laser to be locked from the tunable lasers in bank B, as explained above.

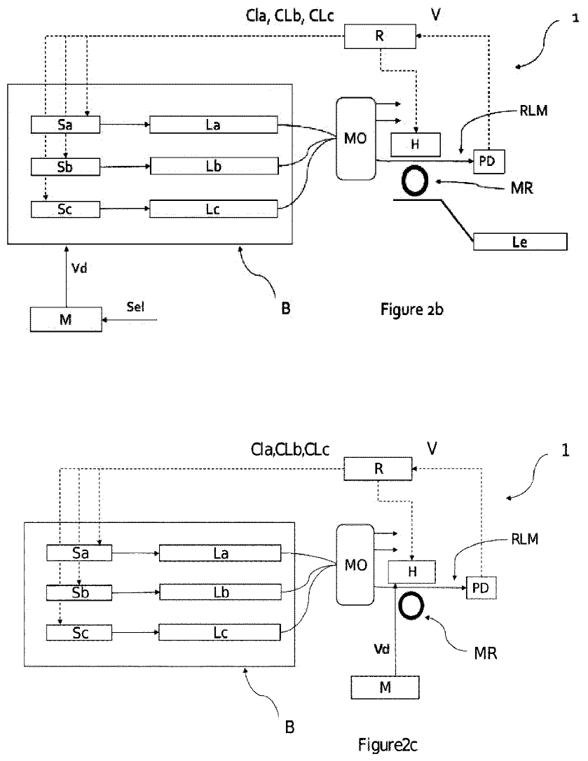

FIG. 4 shows another embodiment of the laser source 1. In this embodiment, each tunable laser La, Lb, Lc in bank B is equipped with a heater Ha, Hb, Hc. As is well known, the heater associated with a laser allows fine control of the laser emission frequency by varying its temperature. In the laser source 1 embodiment, the commands CLa′, CLb′, CLc′ generated by the locking device R are respectively connected to the heaters Ha, Hb, Hc for control purposes. In this embodiment, therefore, the emission frequency of the tunable lasers in bank B is adjusted via the heaters Ha, Hb, Hc, by controlling the temperature of the selected tunable laser, and not by controlling its average supply current, as was the case in the first embodiment. All other elements of the laser source 1 of the second embodiment are identical to those of the first embodiment and, for the sake of brevity, their description will not be repeated. It is of course possible to combine these two embodiments, and to adjust the emission frequency of the tunable lasers in bank B, by controlling both the average supply current of the current source associated with a selected tunable laser and, simultaneously, by controlling the temperature of this laser by means of an associated heater.

In another variant of the embodiments of the laser source 1 shown in FIGS. 2a and 4, each laser La, Lb, Lc in bank B this time includes a carrier injection/depletion device, such as a waveguide arranged under the laser La, Lb, Lc. In the same way, the laser emission frequency can be finely controlled by varying the concentration of free carriers in the device beneath the laser. In the configuration of laser source 1 in this embodiment, the commands CLa′, CLb′, CLc′ generated by the locking device R are respectively connected to the carrier injection/depletion devices.

As already stated, each tunable laser in laser bank B can be provided with a plurality of means for adjusting its emission frequency. In this case, it is not necessary to use the same means to modulate the emission frequency of this laser and to adjust it to a resonant frequency of the filter MR. A first means can thus be used to modulate this emission frequency (e.g., by applying the modulation signal Vd to the supply current source of the selected laser and thus modulating this supply current) and a second means, different from the first, can be used to adjust the emission frequency of this laser to a resonant frequency of the filter (e.g., by controlling the temperature produced by a heater associated with the laser).

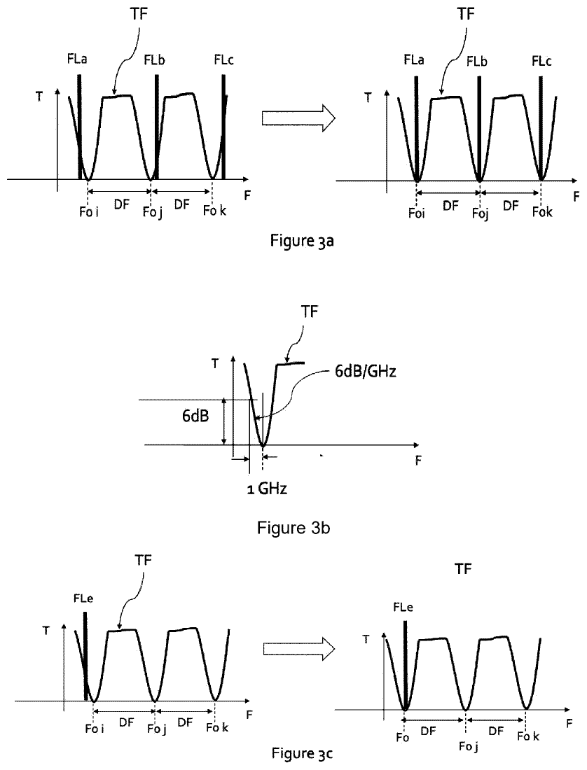

In the frequency-division multiplex mode shown in FIG. 5, modulator M generates a plurality of modulation signals Vda, Vdb, Vdc, each modulation signal being associated with a tunable laser La, Lb, Lc from bank B. Each modulation signal has a modulation frequency Fda, Fdb, Fdc that is distinct from the frequencies of the other modulation signals. These signals are applied simultaneously, and advantageously permanently, to the lasers with which they are respectively associated, in this case to the current sources of these lasers. The modulator M thus modulates the emission frequencies of the tunable lasers via a modulation frequency specific to each tunable laser. For example, modulation frequencies can be in the range 1 kHz to 30 KHz. In the case of this embodiment, the modulator M does not need to be controllable via a selection signal. The remainder of the laser source 1 in this embodiment is identical to the first embodiment in FIG. 2a, and its description will therefore be omitted here for the sake of brevity. In particular, as in the first embodiment, radiation supplied by a standard laser can be injected into a complementary port of the filter MR, and a heater H associated with this filter MR can be used to precisely position each line of the multispectral light radiation RLM in the frequency domain.

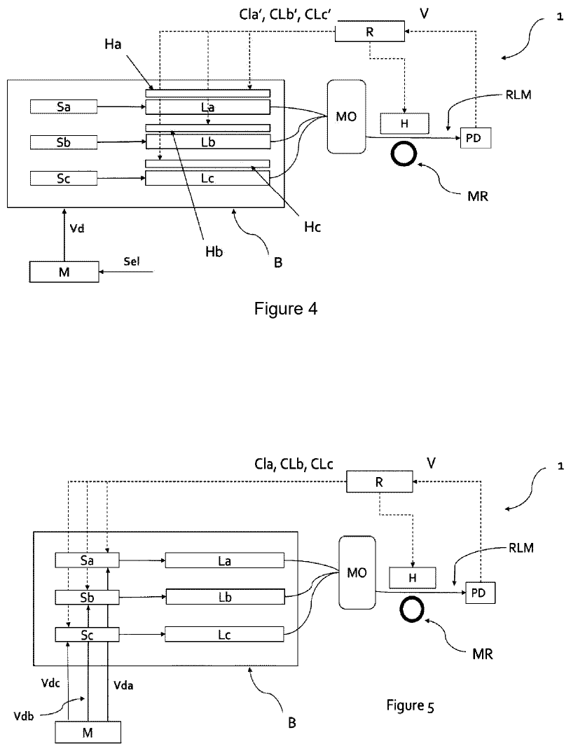

The processes implemented by the locking device R are naturally adapted to this embodiment, but are based on the same principles described in FIGS. 1a to 1e. In particular, the frequency-domain analysis of the signal V supplied by the photodetector reveals, as can be seen in FIG. 6, each of the modulation frequencies and their harmonics. As these modulation frequencies are known, the locking device can be configured to identify them and implement processing to adjust the emission frequency of the associated tunable laser.

In the illustration in FIG. 5, the control signals CLa, CLb, CLc generated by the locking device R are respectively connected to the current sources Sa, Sb, Sc of the bank of tunable lasers. However, as in the embodiment shown in FIG. 4, it is also possible in the embodiment shown in FIG. 5 to control the emission frequency of the tunable lasers using heaters respectively associated with these tunable lasers, or any other means of adjusting the emission frequency of these lasers.

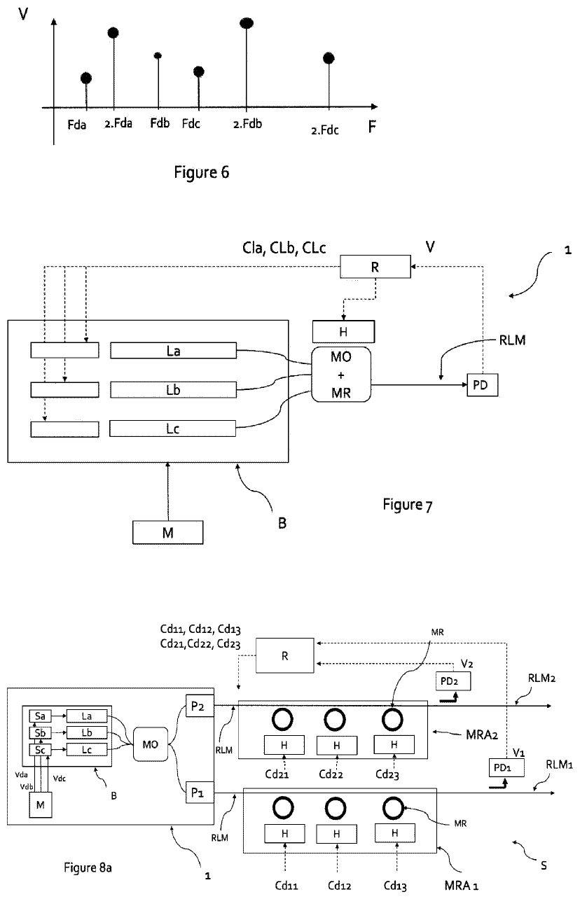

FIG. 7 shows a variant that can be applied to both the above-mentioned embodiments. In this variant, a single optical element (designated MO+MR in the figure) implements the functions of the mixer MO and filter MR. It may be a multiplexer implemented by an arrayed waveguide grating or a ladder network. This element has a transfer function identical to that shown in FIG. 3a.

Whichever embodiment is chosen, a laser source 1 conforming to the invention can be implemented by silicon-based photonic technologies. According to these technologies, waveguides and other passive components are produced on a silicon substrate (and advantageously on a silicon-on-insulator substrate) and other elements (laser sources, photodetectors, optical mixers, heaters) can be formed on this substrate by deposition or transfer. This photonic chip can be combined with an electronic chip comprising some of the other electronic components of the laser source 1, such as the current sources and even the locking device. In some cases, a single chip may comprise the photonic and electronic elements of source 1. The locking device, if not integrated into one of the chips, can be implemented by a computing device (a micro-controller, a signal processing computer DSP or an ASIC) arranged on a support and to which the chip or chips are electrically connected.

It will be noted that a laser source 1 according to the invention is particularly valuable because the emission frequency of the tunable lasers in bank B can be tuned via a particularly simple circuit. This is particularly true of the photonic part of the source, augmented by a single photodetector PD and a single filter MR, such as a micro-ring resonator. This limits the number of additional interconnection pads required on the photonic chip to enable the locking functionality of tunable lasers.

### Second Aspect of the Invention

The multispectral light radiation modulated by the modulation signal Vd, which forms the “useful” radiation supplied by the source, can also be used for the calibration and/or locking of photonic components (routers, modulators, demodulators, etc.) arranged downstream of the laser source 1 when this source 1 is used in a more complex photonic system S. According to this other aspect of the invention, a laser source can be used to provide multispectral light with a poorly controlled spectral range.

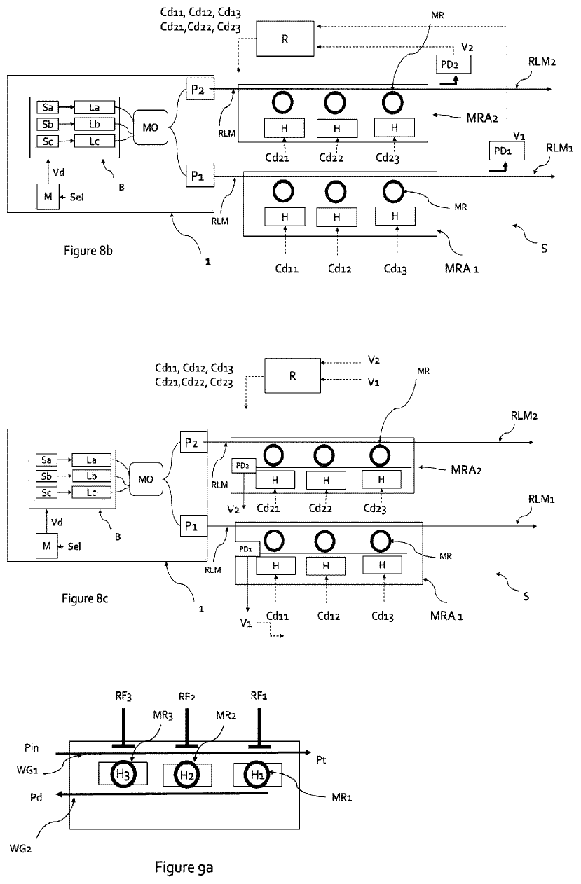

An example of the use of a laser source in accordance with this aspect of the invention is shown in FIG. 8a (frequency-division multiplexing) and FIG. 8b (time-division multiplexing). In these figures, a laser source 1 has at least one output port (two ports P1, P2 in FIGS. 8a, 8b, each producing multispectral light radiation RLM. This radiation is thus spectrally composed of a plurality of lines separated by a spectral interval. At least one of these lines is frequency-modulated, as has been explained in detail in connection with the description of each of the embodiments of source 1 (in time-division or frequency-division multiplexing).

A source 1 according to this aspect of the invention includes a bank B of lasers La, Lb, Lc. Each laser in bank B is associated with a current source Sa, Sb, Sc, forming means for adjusting its emission frequency, connected to the modulator M. In this way, as in the first aspect of the invention, it is possible to modulate at least one emission frequency of the multispectral radiation RLM emitted by source 1. The tunable lasers La, Lb, Lc of bank B are coupled to an optical mixer MO via a waveguide network internal to source 1. The multispectral light radiation RLM produced by the optical mixer MO is guided by the internal waveguide network to a port P1, P2 on source 1. It propagates in an external waveguide coupled to this port P1, P2.

The external waveguide is itself coupled to a photonic component MRA1, MRA2, arranged optically downstream of source 1 and laser bank B, the photonic component comprising a plurality of optical filters with tunable resonant frequencies, respectively. In such a photonic component, the resonant frequency of each filter is individually tunable. The photonic component MRA1, MRA2 conditions the multispectral light radiation received at its input port according to the function performed by this component.

Also, in the example shown in FIGS. 8a, 8b, two radio-frequency modulators MRA1, MRA2, each implementing an array of independent micro-resonators, are respectively optically connected to two ports P1, P2 of the laser source 1. As is well known in the field of telecommunications, a radio-frequency modulator is used to condition each spectral line of multispectral light radiation (here by means of micro-resonators tuned to these lines) in order to transmit information signals in a frequency-division multiplexed manner.

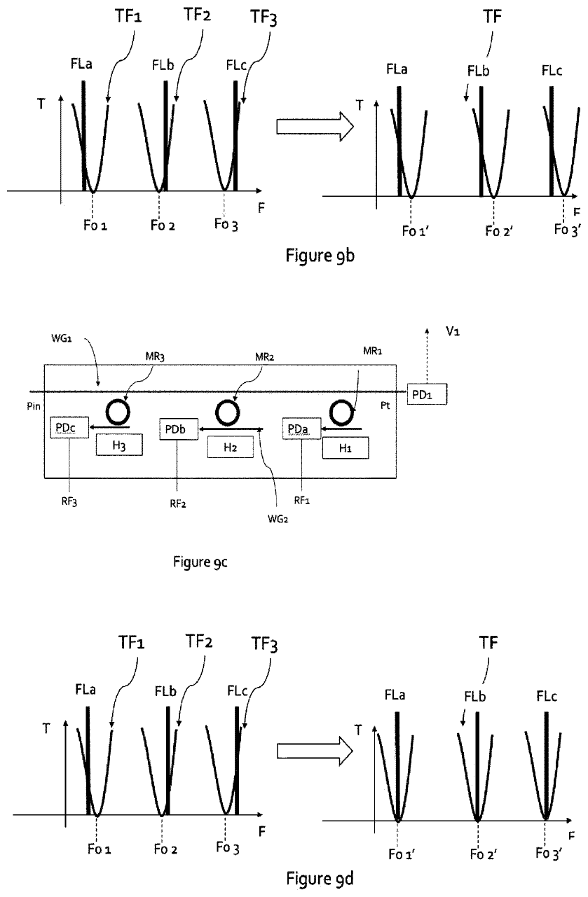

An example of such a radio-frequency modulator is shown in more detail in FIG. 9a. An array of micro-ring resonators MR1-MR3 is arranged between a first and a second waveguide WG1, WG2. The first waveguide WG1 passes through between an input port

Pin, at which the multispectral light radiation to be modulated is supplied, and a so-called “transmission” output port Pt (“through port”), at which the modulated light radiation is produced. The second waveguide WG2 is connected to an output loss port (“drop port”) Pd. Each micro-resonator is operated to modulate a transmission frequency of source 1 via an radio frequency signal RF1-RF3. Each micro-ring resonator MR1-MR3 is associated with a means H1, H2, H3 of adjusting its resonant frequency F01, F02, F03, for example a heater. In such a radio-frequency modulator MRA, the aim is to position the resonant frequency F01, F02, F03 of each micro-resonator MR1-MR3 relative to a spectral line FLa, FLb, FLc of the multispectral radiation produced by source 1, according to the configuration shown in FIG. 1d, that is, in a linear part of the transfer function TF1-TF3 of the micro-resonator MR1-MR3. Naturally, the aim is to allocate a distinct emission line to each micro-resonator. As shown in FIG. 9b, the adjustment means H1-H3 associated with the micro-resonators MR1-MR3 are used to adjust the original resonant frequencies F01, F02, F03 to the optimized frequencies F01′, F02′, F03′.

Returning to the description of FIGS. 8a, 8b, the micro-resonators MR of the radio-frequency modulator micro-resonator MRA1, MRA2 array are respectively associated with adjustment devices H for independently adjusting their resonant frequency, in particular for locking them to the spectral lines with which they are to be associated.

Note that this combination can be made with great flexibility, for example by associating the micro-resonator and the laser whose resonance and emission frequencies are closest. Prior art solutions in which the modulation signal is applied to the micro-resonators do not allow such flexibility, as it is not possible to determine with which laser a micro-resonator is associated.

A monitoring photodetector PD1, PD2 is also provided optically downstream of the photonic component MRA1, MRA2, here at a transmission output port of the photonic component MRA1, MRA2, in order to establish an electrical signal representative of the multispectral radiation RLM1, RLM2. For this purpose, a small portion of this multispectral radiation RLM1, RLM2 can be sampled and coupled to the monitoring photodetectors PD1, PD2, as shown in FIGS. 8a, 8b.

In a variant shown in FIG. 8c, and in order to avoid picking up part of the multispectral radiation RLM1, RLM2 propagating from the transmission port Pt of the photonic component MRA1, MRA2, it may be possible to couple the monitoring photodetector PD1, PD2 directly to a loss port Pt of the photonic component MRA1, MRA2.

A locking device R collects the signal V1, V2 supplied by the monitoring photodetector PD1, PD2 and produces the control signals Cd11, Cd12, Cd13; Cd21, Cd22, Cd23 enabling the adjustment devices H of the optical filters MR making up the photonic component MRA1, MRA2 to be controlled independently and thus to adjust their resonant frequencies to a given emission frequency. The locking device R uses the same principles as those shown in FIGS. 1a to 1e to determine these control signals. When the photonic component MRA1, MRA2 is a modulator, and as already mentioned, it is preferable to position an emission frequency of the multispectral radiation RLM in a linear portion of the transfer function of the filter formed by the micro-resonator. In this way, the ratio between the proportion of signal present in the second harmonic and the proportion of signal present in the main component can be set to equal a target value or to be maximized.

This locking device R can be used for time-division multiplexing FIG. 8b, wherein it is configured to control the modulator M and select the tunable laser La, Lb, Lc to which the modulation signal Vd is applied, by means of the selection signal Sel.

The locking device R can also be used for frequency multiplexing FIG. 8a, wherein

the modulator M generates a plurality of mutually distinct modulation signals Vda, Vdb, Vdc, the modulation signals being applied simultaneously to the tunable lasers La, Lb, Lc. This frequency mode is particularly interesting to exploit, as each filter of the photonic component can be associated and allocated to a particular emission frequency of the multispectral radiation received at the input port.

FIG. 9c shows a demodulator, this demodulator forming another type of optical component MR1, MRA2 that can be calibrated/locked in accordance with the principles of this second aspect of the invention. In such a demodulator, each micro-resonator in the micro-ring resonator MR1-MR3 array is arranged between a first and a second waveguide WG1, WG2. The first waveguide WG1 has an input port Pin, to which the multispectral light radiation to be demodulated can be supplied, and a transmission port Pt. The loss ports of micro-resonators MR1, MR2, MR3 are connected to demodulation photodetectors Pda, PDb, PDc. The photodetector PD1 is placed on the first waveguide WG1 at the transmission port Pt. Each micro-resonator MR1-MR3 filters and extracts radio frequency signals RF1, RF2, RF3 from the multispectral light beam, respectively carried by the emission frequencies (referred to as “carrier frequencies” in this context) FLa, FLb, FLc of the multispectral light radiation. A means H1-H3, such as a heater, for adjusting the resonant frequency F01-F03, is associated with each micro-resonator MR1-MR3.

FIG. 9d shows the relative positioning of resonant frequencies F01, F02, F03 of filters MR1, MR2, MR3 and carrier frequencies FLa, FLb, FLc, before adjustment. Also shown on the right of this FIG. 9d is the relative positioning of the adjusted resonant frequencies F01′, F02′, F03′ and the carrier frequencies FLa, FLb, FLc, after adjustment and in the case where it is deliberately chosen to lock the micro-resonators MR1, MR2, MR3 to the closest optical carriers FLa, FLb, FLc.

Whatever the nature of the photonic device(s) MRA1, MRA2 present in the photonic system, it may be advantageous to engage the system implementation, during a start-up phase, in a frequency multiplexing operation wherein a distinct modulation frequency is applied to each emission/carrier frequency Fla, Flb, FLc of the multispectral light radiation RLM. For simplicity of implementation, it can be decided to produce one after the other, in order to adjust the resonant frequency of one optical filter at a time, the control signals enabling independent control of the adjustment devices H of each micro-resonator MR1, MR2, MR3. As already stated, this method of implementation makes it possible to control the association of a micro-resonator with a carrier frequency, whereas prior art solutions could lead to the association of several micro-resonators with the same carrier frequency. Once this start-up phase has been completed, it can be decided to generate the control signals concurrently.

Naturally, the invention is not limited to the embodiments described, and it is possible to add alternative embodiments without departing from the scope of the invention as defined by the claims.

An optical system in accordance with the invention can exploit either or both of the above aspects. In particular, an optical system combining both aspects of the invention can be provided, that is, featuring a first locking device for adjusting the emission frequencies of the lasers in a bank to the resonant frequencies of a standard filter, and a second locking device for adjusting the resonant frequencies of the optical filters of a photonic component to the emission frequencies of the lasers in the bank.

1. A photonic system comprising a laser source capable of emitting at least one multispectral light radiation having a plurality of spectral lines, the photonic system comprising:
a bank of lasers comprising a plurality of lasers, a spectral line of the multispectral light radiation corresponding to an emission frequency of a laser of the bank;
a modulator associated with the laser bank, the modulator being configured to generate a modulation signal and to modulate the emission frequency of at least one laser of the bank;
a photonic component arranged downstream of the laser bank and comprising a plurality of tunable optical filters each having a plurality of resonant frequencies;
a photodetector arranged downstream of the photonic component to establish a signal representative of multispectral radiation produced by the photonic component; and
a locking device configured to process the signal representative of the multispectral radiation and to adjust the resonant frequencies of the tunable optical filters of the photonic component to the emission frequencies of the lasers in the bank.

2. The photonic system according to claim 1, wherein the tunable optical filters of the photonic component are ring micro-resonators.

3. The photonic system according to claim 1, wherein the tunable optical filters are each provided with devices for adjusting their resonant frequency.

4. The photonic system according to claim 1, wherein the resonant frequency adjustment devices are heaters.

5. The photonic system according to claim 1, wherein the lasers are distributed feedback lasers or distributed Bragg reflector lasers.

6. The photonic system according to claim 1, wherein the locking device is configured to control the modulator and select, by means of a selection signal, a laser from the bank to which the modulation signal is applied.

7. The photonic system according to claim 1, wherein the modulator generates a plurality of modulation signals distinct from one another, the modulation signals being applied to the lasers of the bank.

8. The photonic system according to claim 1, wherein adjustment of the resonant frequencies of the tunable optical filters is performed one optical filter at a time.

9. The photonic system according to claim 1, wherein the modulator is configured to produce a sinusoidal modulation signal having a modulation frequency.

10. The photonic system according to claim 1, wherein the locking device is configured to establish a measurement representative of the power present in a second harmonic of the modulation frequency of the signal representative of the multispectral radiation.

11. The photonic system according to claim 1, wherein the locking device is configured to establish a measurement representative of the power present in a main component of the modulation frequency of the signal representative of the multispectral radiation.

12. The photonic system according to claim 1, wherein the locking device is configured to establish a measurement representative of the phase of the main component of the modulation frequency of the signal representative of the multispectral radiation.

13. The photonic system according to claim 1, wherein the photonic component is a radio-frequency modulator.

14. The photonic system according to claim 1, wherein the photonic component is a radio-frequency demodulator.
